(19) United States
(12) Patent Application Publication
(10) Pub. No.: US 2012/0080677 A1
(43) Pub. Date: Apr. 5, 2012

(54) THIN FILM TRANSISTOR AND MANUFACTURING METHOD THEREOF, THIN FILM TRANSISTOR ARRAY PANEL AND MANUFACTURING METHOD THEREOF

(75) Inventors: Yong-Su LEE, Hwaseong-si (KR); Su-Hyoung KANG, Bucheon-si (KR)

(73) Assignee: SAMSUNG ELECTRONICS CO., LTD., Suwon-si (KR)

(21) Appl. No.: 13/039,096

(22) Filed: Mar. 2, 2011

(30) Foreign Application Priority Data
Oct. 4, 2010 (KR) 10-2010-0096413

(51) Int. Cl. H01L 29/786; H01L 21/28

(52) U.S. Cl. 257/57; 438/158; 257/E21.158; 257/E29.273

(57) ABSTRACT

A manufacturing method of a thin film transistor array panel includes forming a gate line including a gate electrode on a substrate; forming a gate insulating layer on the gate line; forming a semiconductor layer on the gate insulating layer; forming a data line including a data conductive layer pattern on the semiconductor layer and crossing the gate line; forming a planarization layer on the data conductive layer pattern; dry-etching the planarization layer to expose a portion of the data conductive layer pattern overlapping the gate electrode; wet-etching the exposed data conductive layer pattern; and exposing a portion of the semiconductor layer overlapping the gate electrode.

### CROSS REFERENCE TO RELATED APPLICATION

This application claims priority from and the benefit of Korean Patent Application No. 10-2010-0096413, filed on Oct. 4, 2010, which is hereby incorporated by reference for all purposes as if fully set forth herein.

### BACKGROUND OF THE INVENTION

1 Field of the Invention

Exemplary embodiments of the present invention relate to a thin film transistor, a manufacturing method thereof, a thin film transistor array panel, and a manufacturing method thereof.

2. Discussion of the Background

A thin film transistor (TFT) is used in many applications, particularly as a switching and driving element of a display device such as a liquid crystal display (LCD), an organic light emitting diode (OLED) display, and an electrophoretic display.

The thin film transistor includes a gate electrode connected to a gate line transmitting a scanning signal, a source electrode connected to a data line transmitting a signal to be applied to a pixel electrode, a drain electrode facing the source electrode, and a semiconductor electrically connected to the source electrode and the drain electrode. The semiconductor is important for determining characteristics of the thin film transistor. The semiconductor may include mainly silicon.

The silicon in the semiconductor may be amorphous silicon or polysilicon according to its level of crystallization. While amorphous silicon may be manufactured by a simple process, it has low charge mobility, which may limit the performance of a thin film transistor using amorphous silicon. On the other hand, polysilicon may have high charge mobility, but crystallization of the silicon into polysilicon may be required, which potentially increases manufacturing cost using complicated processes.

To mitigate these problems, the channel length of the thin film transistor may be decreased to improve charge mobility. However, it may be difficult to decrease the width of a photosensitive film pattern to pattern the semiconductor within an operating range of a light exposer used in a photolithography process. Also, parasitic capacitance due to alignment error may occur during an exposure process, deteriorating the performance of the thin film transistor.

The above information disclosed in this section is only for enhancement of understanding of the background of the invention, and it may contain information that does not form the prior art.

### SUMMARY OF THE INVENTION

Exemplary embodiments of the present invention provide a thin film transistor that may reduce parasitic capacitance and a thin film transistor array panel including the same.

Exemplary embodiments of the present invention provide a thin film transistor having a self-aligned structure that may be formed without using a photolithography process, resulting in a high-performance thin film transistor with decreased parasitic capacitance.

Additional features of the invention will be set forth in the description which follows and, in part, will be apparent from the description or may be learned by practice of the invention.

An exemplary embodiment of the present invention discloses a method for manufacturing a thin film transistor array panel. The method comprises forming a gate line comprising a gate electrode on a substrate; forming a gate insulating layer on the gate line; forming a semiconductor layer on the gate insulating layer; forming a data line comprising a data conductive layer pattern on the semiconductor layer and crossing the gate line; forming a planarization layer on the data conductive layer pattern; dry-etching the planarization layer to expose a portion of the data conductive layer pattern overlapping the gate electrode; wet-etching the exposed data conductive layer pattern; and exposing a portion of the semiconductor layer overlapping the gate electrode.

An exemplary embodiment of the present invention also discloses a thin film transistor array panel that comprises a substrate; a gate line disposed on the substrate and comprising a gate electrode; a gate insulating layer disposed on the gate electrode and comprising a first upper surface and a second upper surface of different heights; a semiconductor layer disposed on the gate insulating layer; a data line comprising a data conductive layer disposed on the second upper surface of the gate insulating layer and crossing the gate line; and a planarization layer disposed on the data conductive layer and comprising an opening corresponding to the first upper surface of the gate insulating layer. The height of the first upper surface is greater than the height of the second upper surface.

An exemplary embodiment of the present invention additionally discloses a method for manufacturing a thin film transistor. The method comprises forming a gate electrode on a substrate; forming a gate insulating layer on the gate electrode; forming a data conductive layer pattern on the gate insulating layer; forming a planarization layer on the data conductive layer pattern; dry-etching the planarization layer to expose a portion of the data conductive layer pattern overlapping the gate electrode; wet-etching the exposed data conductive layer pattern to expose a portion of the gate insulating layer overlapping the gate electrode; removing the planarization layer; and forming a semiconductor pattern covering the exposed gate insulating layer on the data conductive layer pattern.

An exemplary embodiment of the present invention further discloses a thin film transistor that comprises a substrate; a gate electrode disposed on the substrate; a gate insulating layer disposed on the gate electrode and comprising a first upper surface and a second upper surface of different heights and a lateral surface connecting the first upper surface and the second upper surface; a data conductive layer disposed on the second upper surface and the lateral surface of the gate insulating layer; and a semiconductor layer disposed on the first upper surface and the lateral surface of the gate insulating layer. The data conductive layer is interposed between the gate insulating layer and the semiconductor layer on the lateral surface of the gate insulating layer.

An exemplary embodiment of the present invention also discloses a thin film transistor array panel that comprises a substrate; a gate electrode disposed on the substrate; a gate insulating layer disposed on the gate electrode and comprising a first upper surface and a second upper surface of different heights; a semiconductor layer corresponding to the gate electrode disposed on the gate insulating layer; a source electrode disposed on the second upper surface; a drain electrode disposed on the second upper surface and facing the source electrode, the drain electrode and the source electrode being separated by at least a width of the upper surface of the gate insulating layer; and a planarization layer disposed on the drain electrode and the source electrode and comprising an opening corresponding to the first upper surface of the gate insulating layer. The height of the first upper surface is greater than the height of the second upper surface, and the source electrode and the drain electrode are self-aligned to the gate electrode.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and, together with the description, serve to explain the principles of the invention.

FIG. 1 is a cross-sectional view of a thin film transistor according to an exemplary embodiment of the present invention.

FIG. 2, FIG. 3, FIG. 4, FIG. 5, FIG. 6, FIG. 7, and FIG. 8 are cross-sectional views showing a manufacturing method of the thin film transistor shown in FIG. 1.

FIG. 9 is a cross-sectional view of a thin film transistor according to another exemplary embodiment of the present invention.

FIG. 10, FIG. 11, FIG. 12, FIG. 13, FIG. 14, FIG. 15, and FIG. 16 are cross-sectional views showing a manufacturing method of the thin film transistor shown in FIG. 9.

FIG. 17 is a cross-sectional view of a thin film transistor according to another exemplary embodiment of the present invention.

FIG. 18, FIG. 19, FIG. 20, FIG. 21, and FIG. 22 are cross-sectional views showing a manufacturing method of the thin film transistor shown in FIG. 17.

FIG. 23 is a plan view of a thin film transistor array panel according to another exemplary embodiment of the present invention.

FIG. 24 is a cross-sectional view taken along line A-B and line C-D of FIG. 23.

FIG. 25, FIG. 26, FIG. 27, FIG. 28, FIG. 29, FIG. 30, FIG. 31, FIG. 32, FIG. 33, FIG. 34, FIG. 35, and FIG. 36 are cross-sectional views showing a manufacturing method of the thin film transistor array panel shown in FIG. 23.

### DETAILED DESCRIPTION OF THE ILLUSTRATED EMBODIMENTS

The invention is described more fully hereinafter with reference to the accompanying drawings in which embodiments of the invention are shown. This invention may, however, be embodied in many different forms and should not be construed as limited to the embodiments set forth herein. Rather, these embodiments are provided so that this disclosure is thorough and will fully convey the scope of the invention to those skilled in the art. In the drawings, the size and relative sizes of layers and regions may be exaggerated for clarity Like reference numerals in the drawings denote like elements.

It will be understood that when an element or layer is referred to as being “on,” “connected to,” or “coupled to” another element or layer, it can be directly on, directly connected to, directly coupled to the other element or layer, or intervening elements or layers may be present. In contrast, when an element is referred to as being “directly on,” “directly connected to,” or “directly coupled to” another element or layer, there are no intervening elements or layers present.

In the drawings, the thickness of layers and regions may be exaggerated for clarity. Like elements are denoted by like reference numerals in the specification.

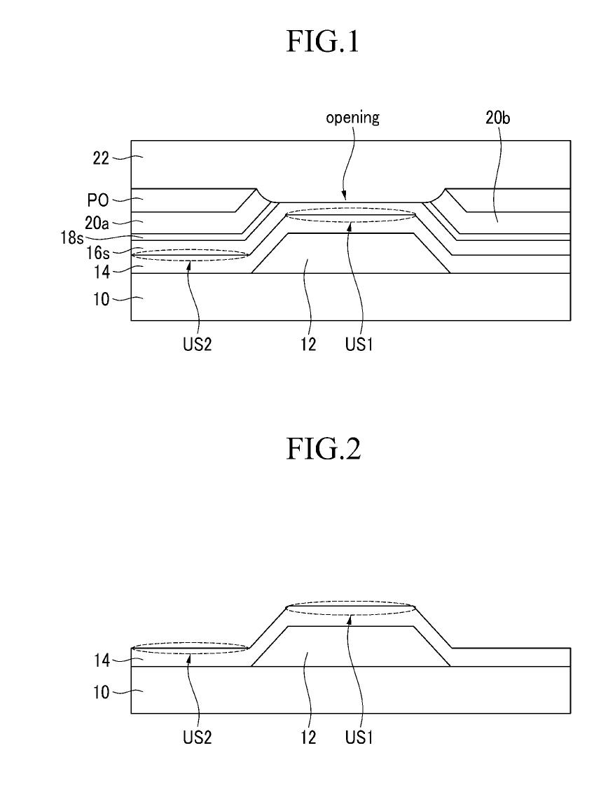

FIG. 1 is a cross-sectional view of a thin film transistor according to an exemplary embodiment of the present invention.

Referring to FIG. 1, a gate electrode 12 and a gate insulating layer 14 covering the gate electrode 12 are formed on a substrate 10, and the gate insulating layer 14 has a stepped structure due to the height of the gate electrode 12. As a result, the gate insulating layer 14 may have a first upper surface US1 and a second upper surface US2 having different heights from each other. The first upper surface US1 is positioned corresponding to the gate electrode 12 and has a higher height than the height of the second upper surface US2.

A semiconductor layer including a semiconductor 16s and an ohmic contact layer 18s is positioned on the gate insulating layer 14. The semiconductor 16s may contain amorphous silicon, polysilicon, or an oxide semiconductor, and the ohmic contact layer 18s may contain amorphous silicon doped with a conductive impurity or of a silicide. The oxide semiconductor may be, for example, indium oxide (InO), gallium oxide (GaO), or zinc oxide (ZnO). The ohmic contact layer 18s is positioned on the semiconductor 16s, however and exposes the semiconductor 16s positioned on the first upper surface US1 of the gate insulating layer 14.

A data conductive layer pattern is positioned on the ohmic contact layer 18s. The data conductive layer pattern includes a source electrode 20a and a drain electrode 20b that are separated from each other with respect to the exposed portion of the semiconductor 16s positioned on the first upper surface US1.

A planarization layer PO is formed on the source electrode 20a and the drain electrode 20b. Here, the planarization layer PO does not overlap the first upper surface US1 of the gate insulating layer 14. That is, the planarization layer PO has an opening that overlaps the first upper surface US1 of the gate insulating layer 14. To obtain the opening, the planarization layer PO may be etched in a manufacturing process according to an exemplary embodiment of the present invention.

A passivation layer 22 covering the exposed semiconductor 16s positioned on the first upper surface US1 may be formed on the planarization layer PO.

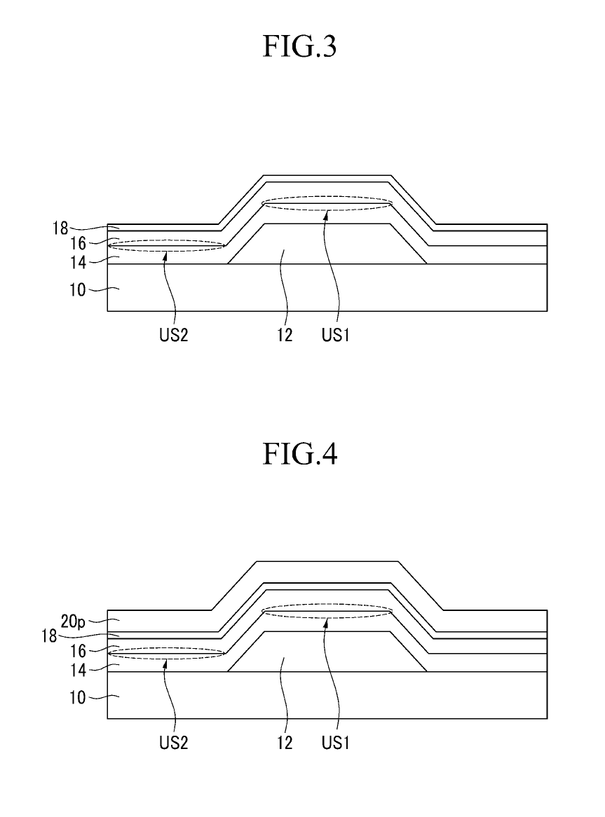

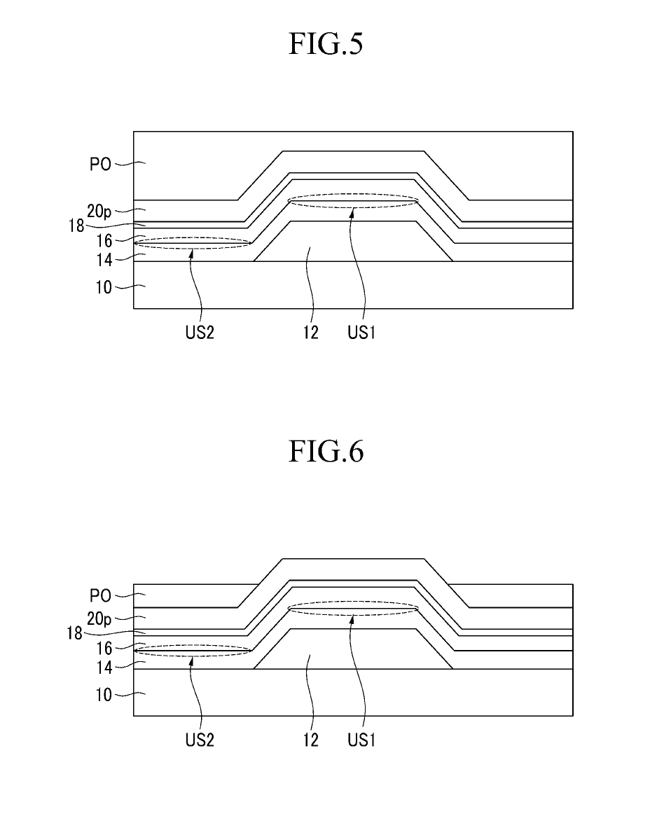

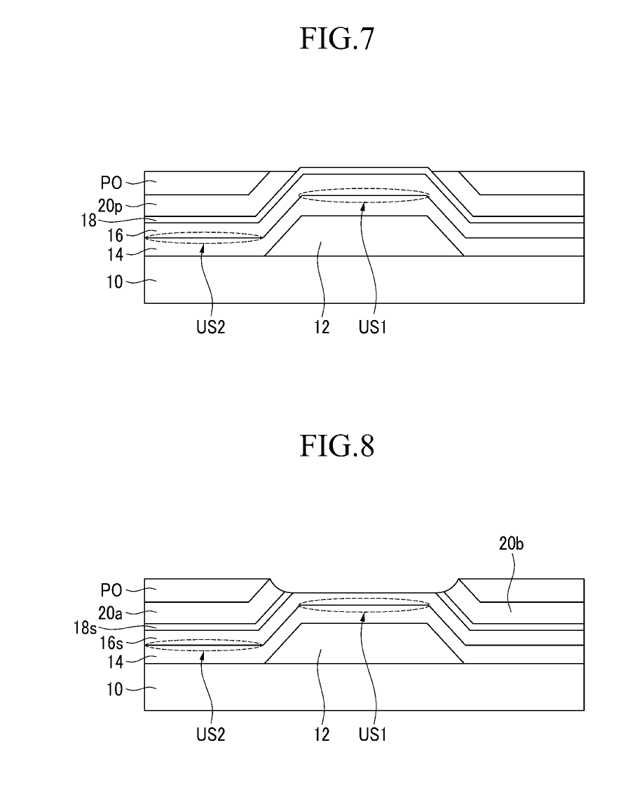

FIG. 2, FIG. 3, FIG. 4, FIG. 5, FIG. 6, FIG. 7, and FIG. 8 are cross-sectional views showing a manufacturing method of the thin film transistor shown in FIG. 1.

Referring to FIG. 2, after a gate electrode 12 is formed on a substrate 10 through a photolithography process, a gate insulating layer 14 covering the gate electrode 12 is formed. The gate insulating layer 14 covers the gate electrode 12 on the substrate 10 such that it may have the step, and the first upper surface US1 and the second upper surface US2 have different heights.

Referring to FIG. 3, a first silicon layer 16 and a second silicon layer 18 are sequentially deposited on the gate insulating layer 14.

The first silicon layer 16 may be made of amorphous silicon, polysilicon, or an oxide semiconductor, and the second silicon layer 18 may be made of amorphous silicon doped with an impurity or of silicide. The oxide semiconductor may include InO, GaO, or ZnO.

Referring to FIG. 4, a data conductive layer (not shown) is formed on the second silicon layer 18. Here, the data conductive layer forms the step due to the thickness of the gate electrode 12. The data conductive layer is patterned to form a data conductive layer pattern 20p, and the second silicon layer 18 and the first silicon layer 16 are sequentially etched using the data conductive layer pattern 20p as a mask. In contrast to conventional methods, the data conductive layer pattern 20p is not divided into a source electrode and a drain electrode but is a continuous layer overlapping the upper surface US1 of the gate insulating layer 14.

Referring to FIG. 5, a planarization layer PO covering the data conductive layer pattern 20p is formed. The planarization layer PO completely covers the data conductive layer pattern 20p that protrudes by the thickness of the gate electrode 12. The planarization layer PO may contain an insulating material such as an organic material, silicon nitride, or silicon oxide.

Referring to FIG. 6, the planarization layer PO is dry-etched to expose the protruding portion of the data conductive layer pattern 20p. The exposed data conductive layer pattern 20p is therefore self-aligned with the gate electrode 12.

Referring to FIG. 7, the exposed data conductive layer pattern 20p is wet-etched to expose the second silicon layer 18.

Referring to FIG. 8, the exposed second silicon layer 18 is dry-etched to remove a portion thereof and expose the first silicon layer 16. Here, the portion positioned on the first upper surface US1 of the gate insulating layer 12 is formed into the exposed semiconductor 16s and the ohmic contact layer 18s, and the source electrode 20a and the drain electrode 20b that are separated from each other with respect to the exposed semiconductor 16s may be formed.

The semiconductor 16s may be formed by etching a portion of the upper surface of the first silicon layer 16.

A passivation layer 22 covering the exposed semiconductor 16s positioned on the first upper surface US1 is formed on the planarization layer PO to manufacture the thin film transistor shown in FIG. 1.

As described above in the present exemplary embodiment, when several etch processes are repeated without a photolithography process, the source electrode 20a and the drain electrode 20b may be self-aligned such that the parasitic capacitance caused by overlapping the gate electrode 12 and the source electrode 20a and drain electrode 20b may be constantly maintained. That is, in conventional methods, when the source electrode and the drain electrode are formed through photolithography processes using an additional mask that may be twisted with respect to the gate electrode, the overlapping areas between the gate electrode and the source and drain electrodes are changed such that the parasitic capacitance may be changed.

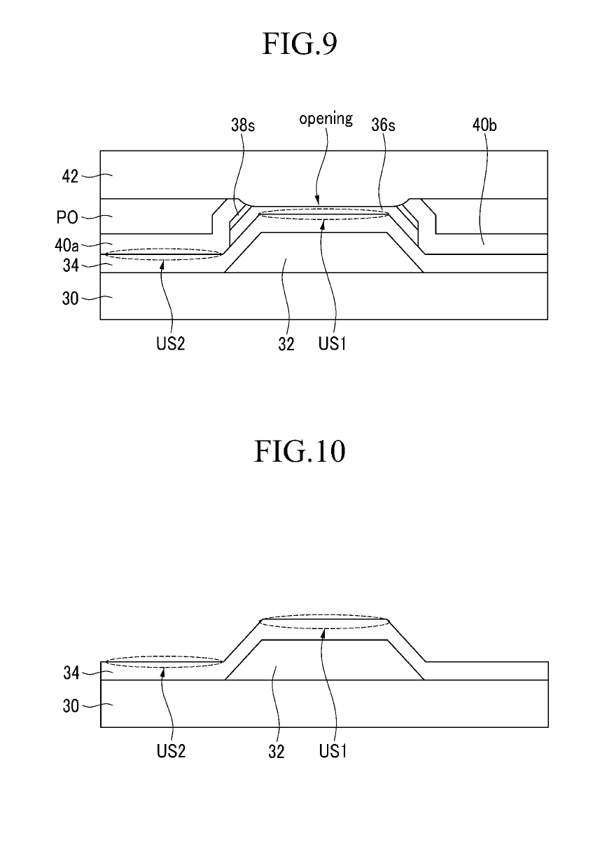

FIG. 9 is a cross-sectional view of a thin film transistor according to another exemplary embodiment of the present invention.

Referring to FIG. 9, a gate electrode 32 and a gate insulating layer 34 covering the gate electrode 32 are formed on a substrate 30. The gate insulating layer 34 covering the gate electrode 32 is formed on the substrate 30 such that the gate insulating layer 34 may have a step so that the first upper surface US1 and the second upper surface US2 may have different heights. The first upper surface US1 corresponds to a position overlapping the gate electrode 32 and is higher than the second upper surface US2.

A semiconductor layer including a semiconductor 36s and an ohmic contact layer 38s is positioned on the gate insulating layer 34.

The semiconductor 36s may be made of amorphous silicon, polysilicon, or an oxide semiconductor, and the ohmic contact layer 38s may be made of amorphous silicon doped with a conductive impurity or may be made of a silicide. The oxide semiconductor may contain, for example, InO, GaO, or ZnO.

A data conductive layer pattern is formed on the gate insulating layer 34. The data conductive layer pattern includes a source electrode 40a and a drain electrode 40b that are separated with respect to the exposed semiconductor 36s positioned on the first upper surface US1. Portions of the source electrode 40a and the drain electrode 40b respectively contact the ohmic contact layer 38s.

The gate insulating layer 34 and the data conductive layer pattern contact on the second upper surface US2 of the gate insulating layer 34.

A planarization layer PO is positioned on the source electrode 40a and the drain electrode 40b. Here, the planarization layer PO does not overlap the first upper surface US1 of the gate insulating layer 34. That is, the planarization layer PO has an opening overlapping the first upper surface US1 of the gate insulating layer 34. The opening of he planarization layer PO may be formed by etching the planarization layer PO in a manufacturing process according to an exemplary embodiment of the present invention.

A passivation layer 42 covering the exposed semiconductor 36s positioned on the first upper surface US1 is formed on the planarization layer PO.

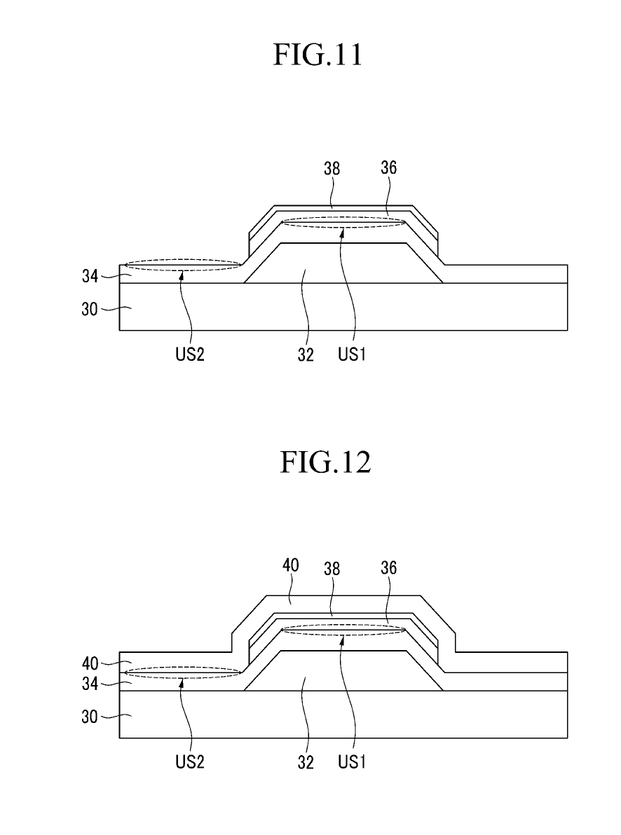

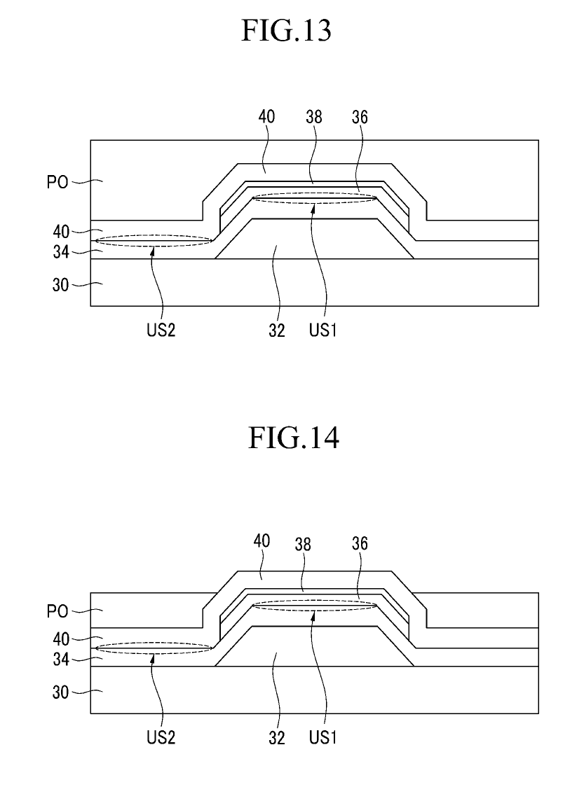

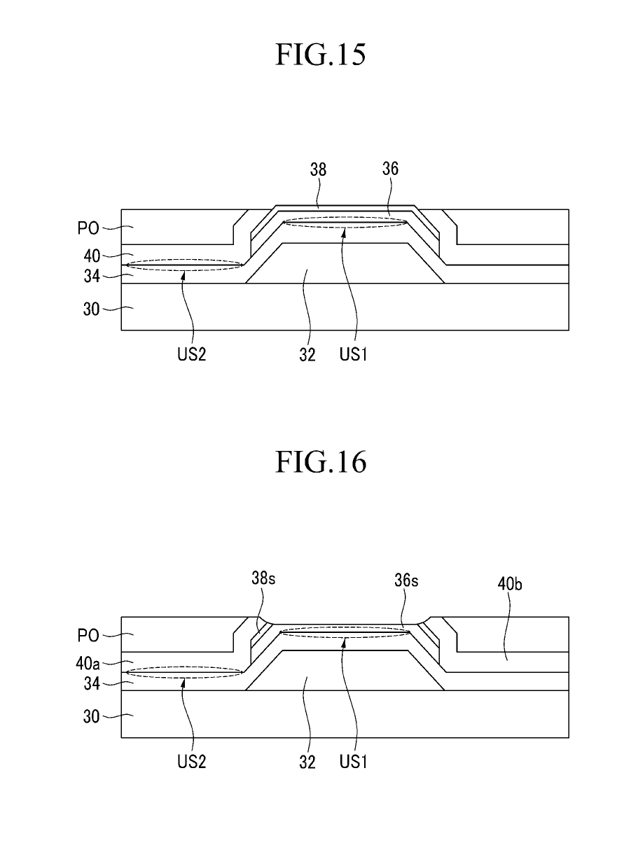

FIG. 10, FIG. 11, FIG. 12, FIG. 13, FIG. 14, FIG. 15, and FIG. 16 are cross-sectional views showing a manufacturing method of the thin film transistor shown in FIG. 9.

Referring to FIG. 10, after a gate electrode 32 is formed on a substrate 30 through a photolithography process, a gate insulating layer 34 covering the gate electrode 32 is formed. The gate insulating layer 34 covers the gate electrode 32 on the substrate 10 such that it may have the step and the first upper surface US1 and the second upper surface US2 having different heights.

Referring to FIG. 11, a first silicon layer 36 and a second silicon layer 38 are formed on the gate insulating layer 34. The first silicon layer 36 and the second silicon layer 38 may be formed by sequentially depositing and patterning a first silicon material and a second silicon material. The first silicon layer 36 may be made of amorphous silicon, polysilicon, or an oxide semiconductor, and the second silicon layer 38 may be made of amorphous silicon doped with a conductive impurity or may be made of a silicide. The oxide semiconductor may be, for example, InO, GaO, or ZnO.

Referring to FIG. 12, a data conductive layer pattern 40 covering the first silicon layer 36 and the second silicon layer 38 is formed on the gate insulating layer 34. The data conductive layer pattern 40 may be patterned through a photolithography process after depositing the data conductive material.

Referring to FIG. 13, a planarization layer PO covering the data conductive layer pattern 40 is formed. The planarization layer PO may be formed to completely cover the data conductive layer pattern 40 that protrudes by the thickness of the gate electrode 32.

Referring to FIG. 14, the planarization layer PO is dry-etched to expose the protruding portion of the data conductive layer pattern 40 that is raised by the thickness of the gate electrode 32. The exposed data conductive layer pattern 40 is therefore self-aligned with the gate electrode 32.

Referring to FIG. 15, the exposed data conductive layer pattern 40 is wet-etched to expose the second silicon layer 38.

Referring to FIG. 16, the exposed second silicon layer 38 is dry-etched. Here, portions of the first silicon layer 36 and the second silicon layer 38 positioned on the first upper surface US1 of the gate insulating layer 34 form the exposed semiconductor 36s and the ohmic contact layer 38s, respectively, and the source electrode 40a and the drain electrode 40b that are separated with respect to the exposed semiconductor 36s may be formed. The semiconductor 36s may be formed by etching the portion of the upper surface of the first silicon layer 36.

A passivation layer 42 covering the exposed semiconductor 36s positioned on the first upper surface US1 is formed on the planarization layer PO to manufacture the thin film transistor of FIG. 9.

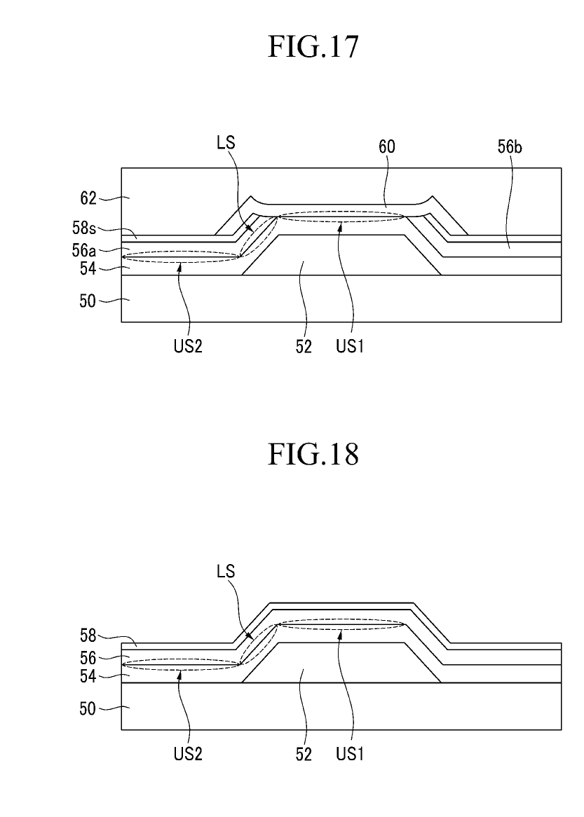

FIG. 17 is a cross-sectional view of a thin film transistor according to another exemplary embodiment of the present invention.

Referring to FIG. 17, a gate electrode 52 and a gate insulating layer 54 covering the gate electrode 52 are formed on a substrate 50. The gate insulating layer 54 covers the gate electrode 52 on the substrate 50 such that the gate insulating layer 54 may have a step including the first upper surface US1 and the second upper surface US2 having different heights, and the lateral surface LS connecting the first upper surface US1 and the second upper surface US2.

The first upper surface US1 corresponds to a portion overlapping the gate electrode 52 and has a higher height than the second upper surface US2.

A data conductive layer pattern is positioned on the gate insulating layer 54. The data conductive layer pattern includes a source electrode 56a and a drain electrode 56b positioned on the second upper surface US2 and the lateral surface LS. The source electrode 56a and the drain electrode 56b are separated from each other with respect to the first upper surface US1.

An ohmic contact layer 58s is positioned on the source electrode 56a and the drain electrode 56b. A semiconductor 60 is positioned to cover the gate insulating layer 54 and the ohmic contact layer 58 on the first upper surface US1 and the lateral surface LS. A passivation layer 62 covering the semiconductor 60 may be positioned on the ohmic contact layer 58.

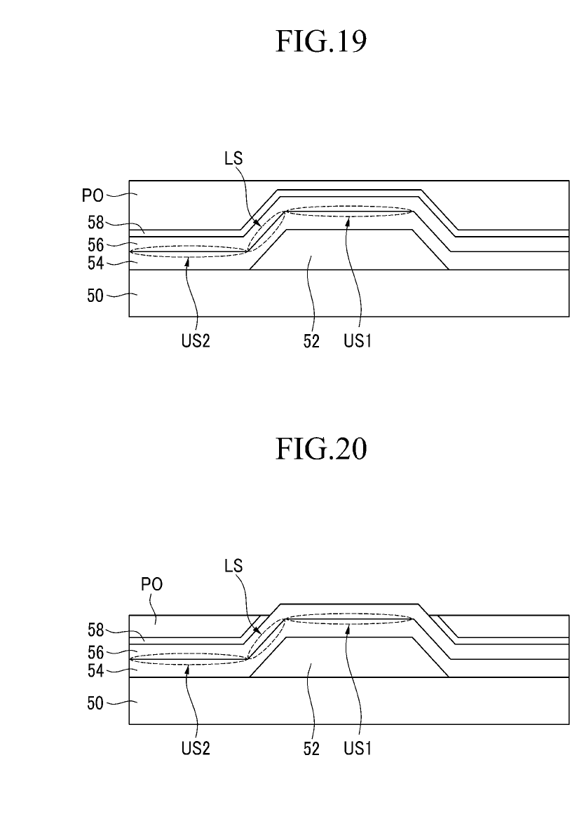

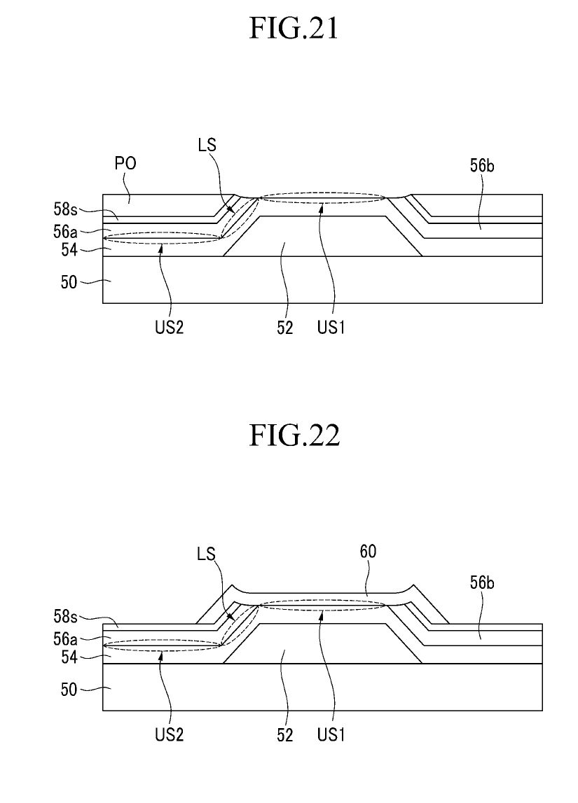

FIG. 18, FIG. 19, FIG. 20, FIG. 21, and FIG. 22 are cross-sectional views showing a manufacturing method of the thin film transistor shown in FIG. 17.

Referring to FIG. 18, a gate electrode 52 is formed on a substrate 50 through a photolithography process, and then a gate insulating layer 54 covering the gate electrode 52 is formed. The gate insulating layer 54 covers the gate electrode 52 on the substrate 50 such that it may have the step forming the first upper surface US1 and the second upper surface US2 having the different heights as well as the lateral surface LS connecting the first upper surface US1 and the second upper surface US2. The first upper surface US1 corresponds to the position overlapping the gate electrode 52 and has a higher height than the second upper surface US2.

A data conductive layer pattern 56 and an ohmic contact layer pattern 58 are formed on the gate insulating layer 54. The data conductive layer pattern 56 and the ohmic contact layer pattern 58 may be formed by depositing and patterning a data conductive layer and a silicon layer on the gate insulating layer 54 by a photolithography process.

Referring to FIG. 19, a planarization layer PO is formed on the ohmic contact layer pattern 58. The planarization layer PO completely covers the data conductive layer pattern 56 and the ohmic contact layer pattern 58 that are raised by the thickness of the gate electrode 52.

Referring to FIG. 20, the planarization layer PO and the ohmic contact layer pattern 58 are simultaneously dry-etched to expose the protruding portion of the data conductive layer pattern 56 that is raised by the thickness of the gate electrode 52. The exposed data conductive layer pattern 56 is therefore self-aligned with the gate electrode 52.

Referring to FIG. 21, the exposed data conductive layer pattern 56 is wet-etched to expose the first upper surface US1 of the gate insulating layer 54. Here, an ohmic contact layer 58s may be formed, and the source electrode 56a and the drain electrode 56b that are separated from each other with respect to the first upper surface US1 may be formed. The ohmic contact layer 58s may be made of amorphous silicon doped with a conductive impurity or may be made of a silicide.

Referring to FIG. 22, after removing the planarization layer PO, a semiconductor 60 covering the gate insulating layer 54 and the ohmic contact layer 58 is formed on the first upper surface US1 and the lateral surface LS. The semiconductor 60 may be formed by forming the semiconductor layer covering the ohmic contact layer 58s and the first upper surface US1 of the gate insulating layer 54 and patterning it through a photolithography process. The semiconductor 60 may be made of amorphous silicon, polysilicon, or an oxide semiconductor. The oxide semiconductor may be InO, GaO, or ZnO. A passivation layer 62 covering the semiconductor 60 is formed on the ohmic contact layer 58s to manufacture the thin film transistor shown in FIG. 17.

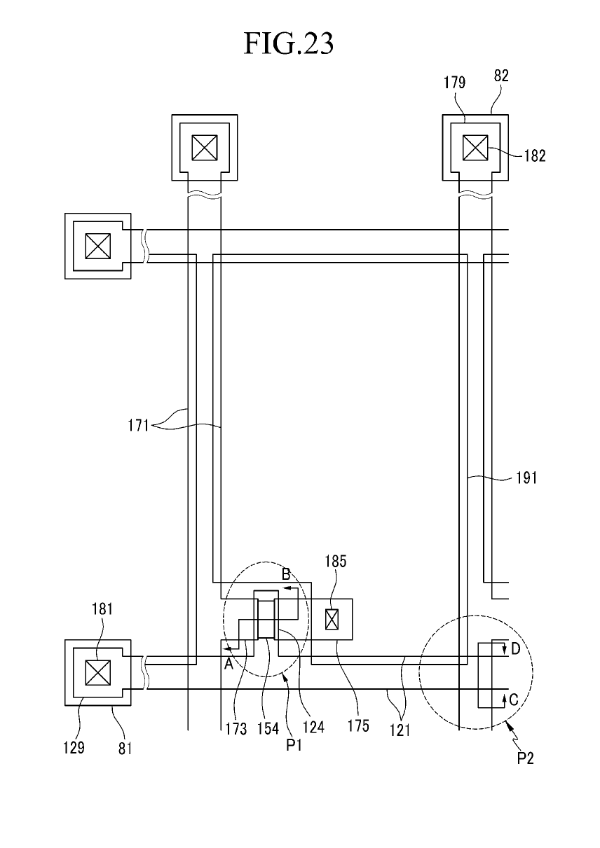

FIG. 23 is plan view of a thin film transistor array panel according to another exemplary embodiment of the present invention.

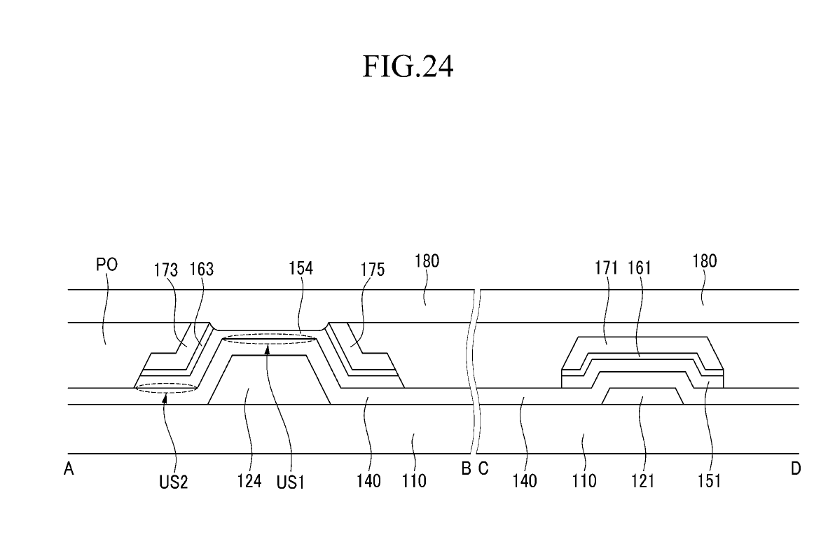

FIG. 24 is a cross-sectional view taken along line A-B and line C-D of FIG. 23.

Referring to FIG. 23 and FIG. 24, in a thin film transistor array panel according to an exemplary embodiment of the present invention, a plurality of gate lines 121 transmitting a gate signal are formed on a substrate 110. Each gate line 121 includes a gate electrode 124 protruding upward and an end 129 having a wide area for connection with an external circuit.

A gate insulating layer 140 is formed on the gate line 121, and a semiconductor 154, which may be made of amorphous silicon, crystallized silicon, or an oxide semiconductor, is formed on the gate insulating layer 140. The gate insulating layer 140 covers the gate electrode 124 on the substrate 110 such that it may have a step including the first upper surface US1 and the second upper surface US2 having different heights from each other. The first upper surface US1 overlaps the gate electrode 124 and has a higher height than the second upper surface US2.

An ohmic contact layer 163, which may contain a silicide or an n+ hydrogenated amorphous silicon doped with an n-type impurity at a high concentration, is formed on the semiconductor 154. A plurality of data lines 171 and a plurality of drain electrodes 175 are formed on the ohmic contact layer 163 and the gate insulating layer 140. Each data line 171 transmitting a data voltage extends in a longitudinal direction and crosses the gate line 121. A plurality of branches extending toward the drain electrodes 175 from the data lines 171 form source electrodes 173, and a pair of a source electrode 173 and a drain electrode 175 face each other on the gate electrode 124. The gate electrode 124, the source electrode 173, and the drain electrode 175 form a TFT together with the semiconductor 154, and a channel of the TFT is formed in the semiconductor 154 between the source electrode 173 and the drain electrode 175.

The semiconductor 154 and the ohmic contact layer 163 may respectively include a semiconductor stripe 151 and an ohmic contact stripe 161 extending in the longitudinal direction. The semiconductor stripe 151 and the semiconductor 154 (except for the channel region between the source electrode 173 and the drain electrode 175) have substantially the same planar shape as the data line 171 and the drain electrode 175. The ohmic contact stripe 161 is interposed between the semiconductor stripe 151 and the data line 171, and the ohmic contact layer 163 is interposed between the semiconductor 154 and the source and drain electrodes 173 and 175. The ohmic contact stripe 161 and ohmic contact layer 163 may have substantially the same planar shapes as the data line 171 and the source and drain electrodes 173 and 175.

A planarization layer PO is formed on the source electrode 173 and the drain electrode 175. Here, the planarization layer PO is not formed at a portion overlapping the first upper surface US1 of the gate insulating layer 140. That is, the planarization layer PO has an opening overlapping the first upper surface US1 of the gate insulating layer 140. The opening may be formed by etching the planarization layer PO in a manufacturing process according to an exemplary embodiment of the present invention.

A passivation layer 180 covering the exposed semiconductor 154 on the first upper surface US1 is formed on the planarization layer PO.

The thin film transistor array panel according to an exemplary embodiment of the present invention includes the first region P1 where the thin film transistor is formed and the second region P2 where the gate line 121 and the data line 171 cross. The first region P1 is described above, and the second region P2 is described below.

In the second region P2 (where the gate line 121 crosses the data line 171), the planarization layer PO completely covers the upper surface of the data line 171 because the thickness of the gate line 121 in the second region P2 is thinner than the thickness of the gate line 121 including the gate electrode 124 in the first region P1.

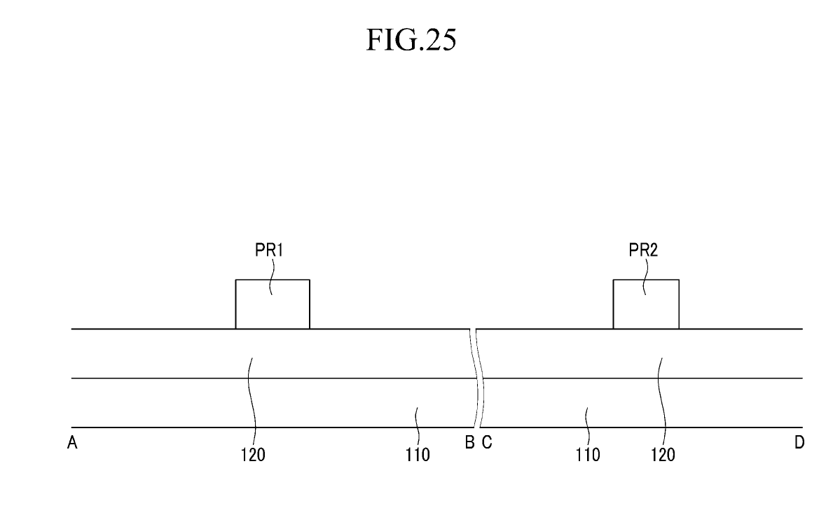

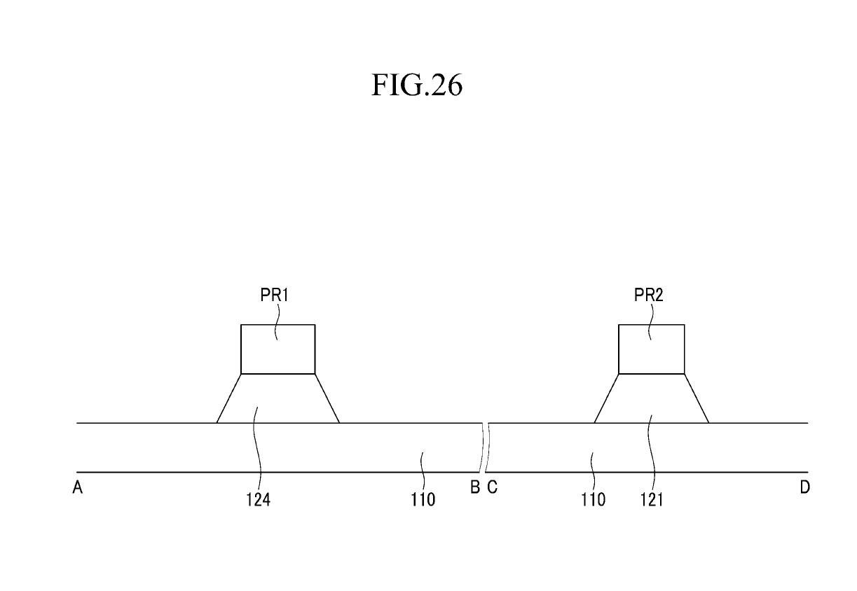

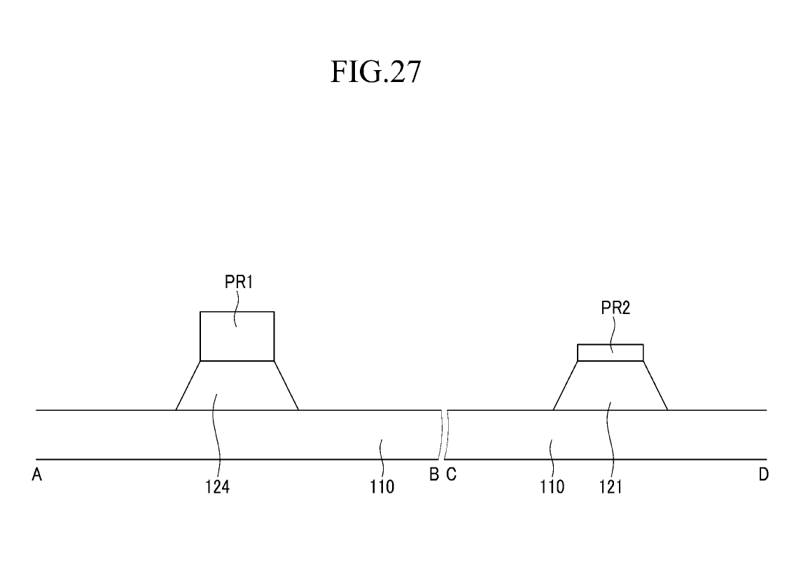

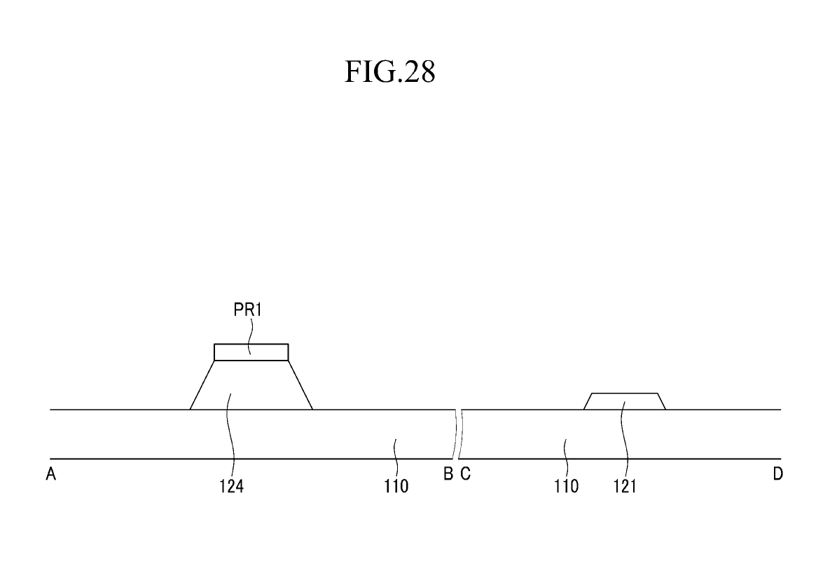

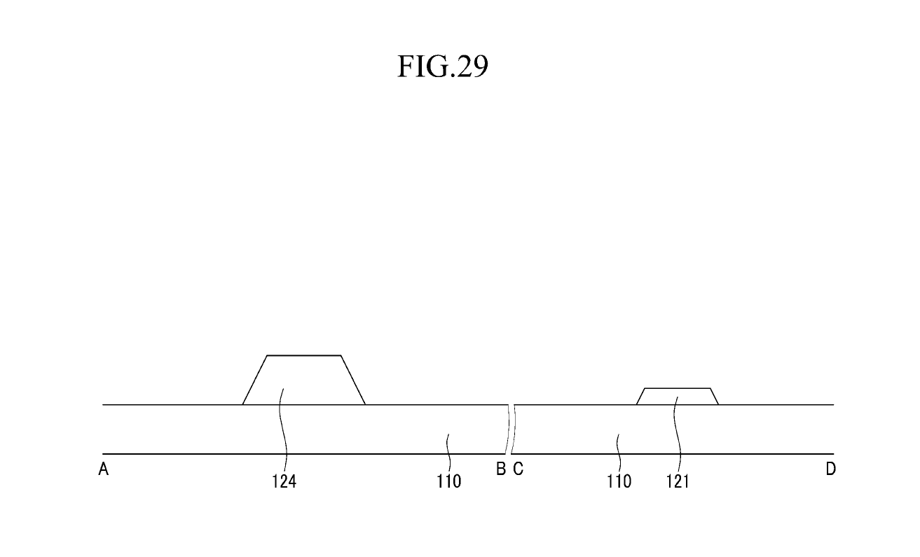

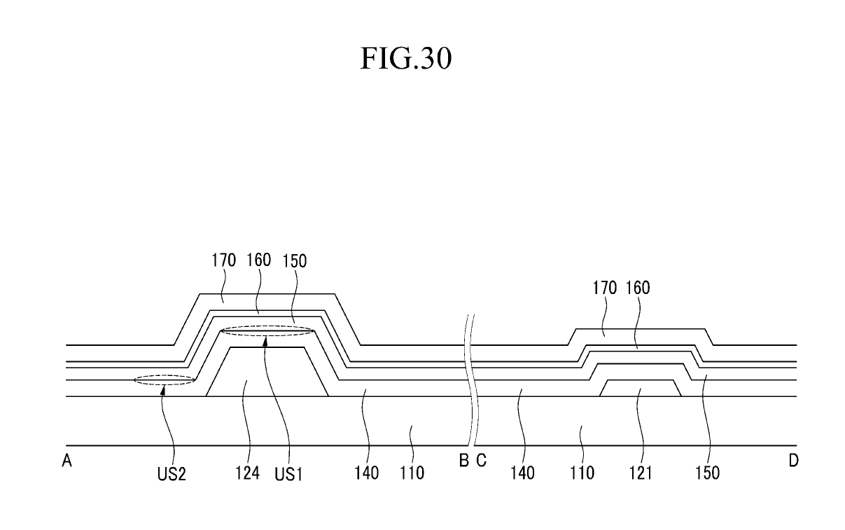

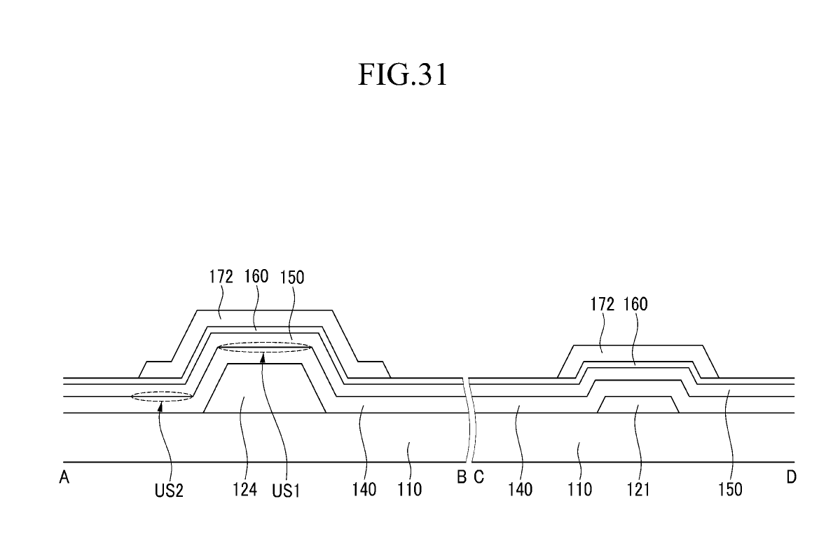

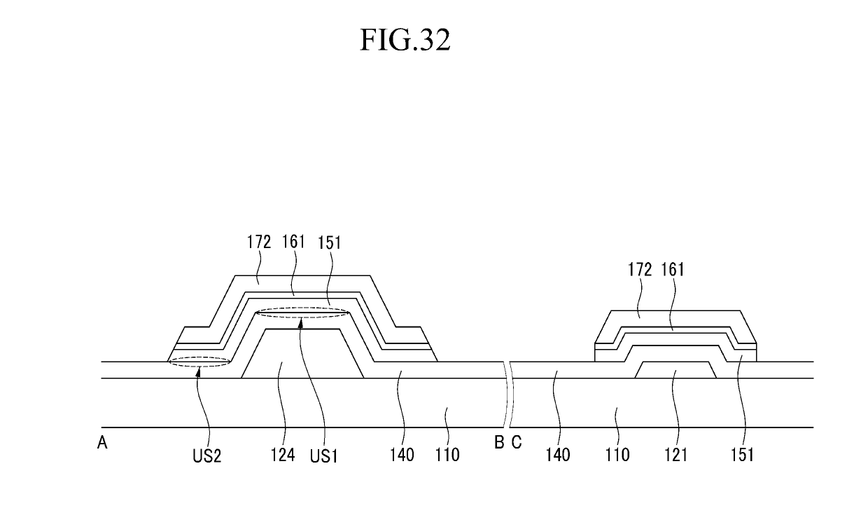

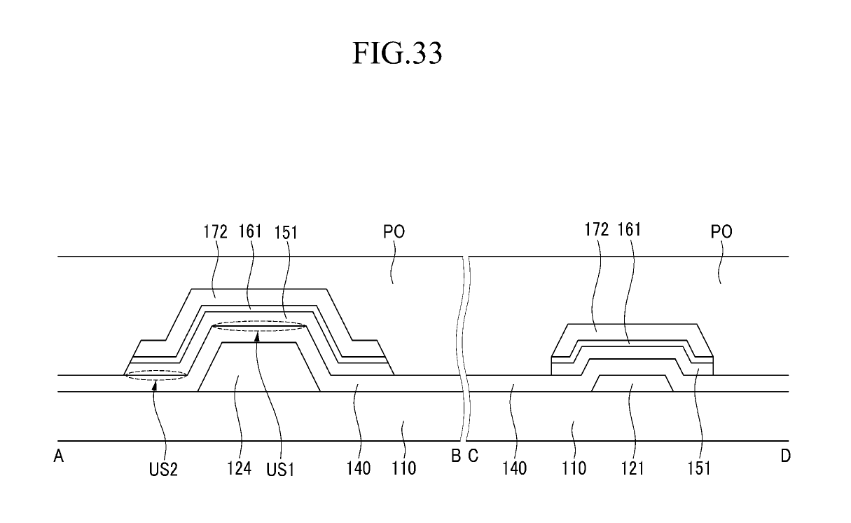

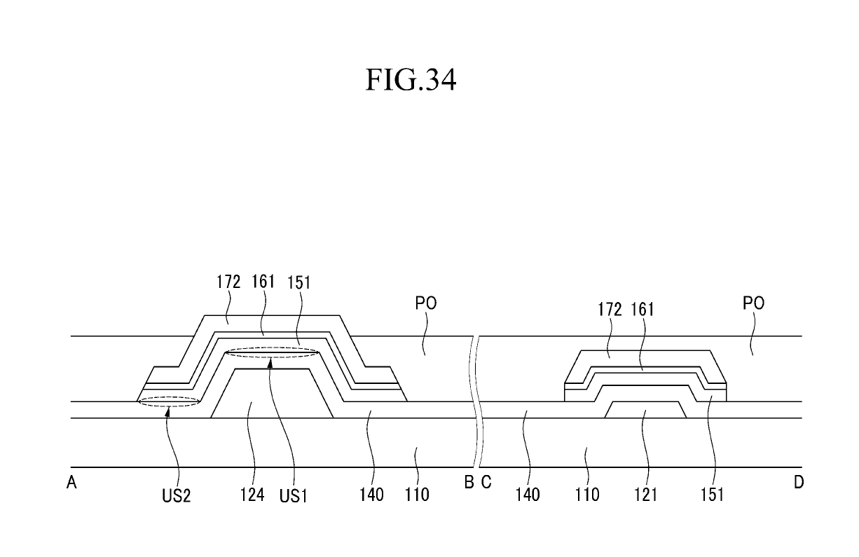

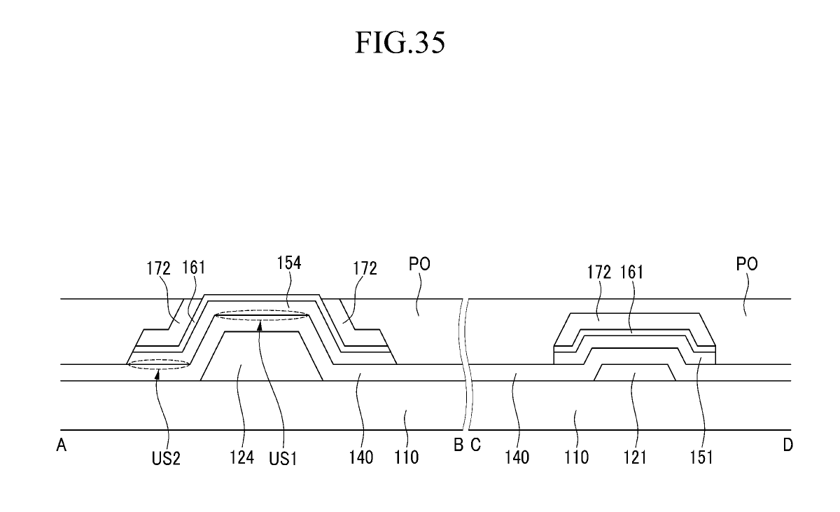

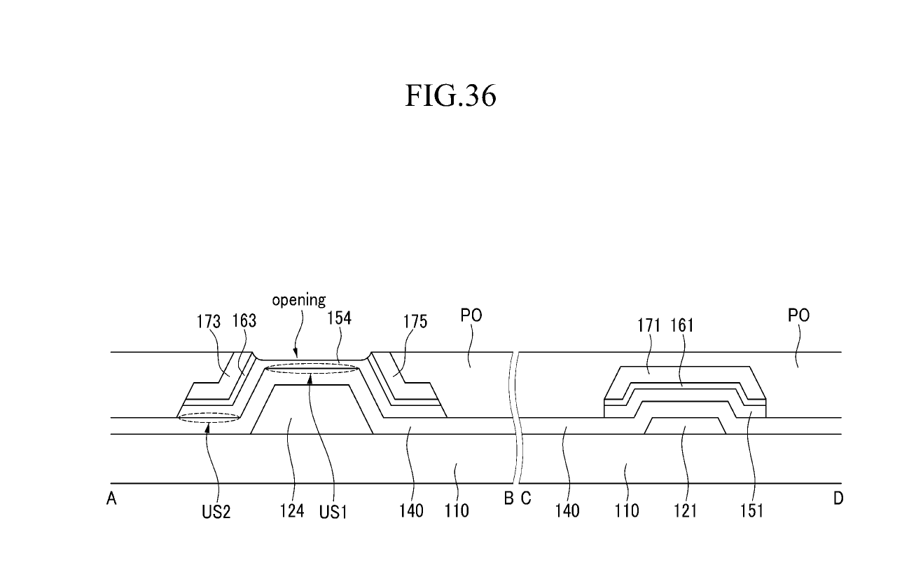

FIG. 25, FIG. 26, FIG. 27, FIG. 28, FIG. 29, FIG. 30, FIG. 31, FIG. 32, FIG. 33, FIG. 34, FIG. 35, and FIG. 36 are cross-sectional views of a manufacturing method of the thin film transistor array panel shown in FIG. 23.

Referring to FIG. 25, a gate conductive material 120 is deposited on a substrate 110, and photosensitive film patterns PR1 and PR2 are formed on the gate conductive material 120.

Referring to FIG. 26, the gate conductive material 120 is etched by using the photosensitive film patterns PR1 and PR2 as a mask to form a gate line 121 including a gate electrode 124.

Referring to FIG. 27, the second photosensitive film pattern PR2 positioned at the second region P2 is processed through a partial ashing process to form a thinner thickness than that of the first photosensitive film pattern PR1 positioned at the first region P1.

Referring to FIG. 28 and FIG. 29, the gate line 121 is etched while using the first photosensitive film pattern PR1 and the second photosensitive film pattern PR2 as masks. The second photosensitive film pattern PR2 is removed such that the gate line 121 positioned at the second region P2 may be etched. Accordingly, the gate line 121 and gate electrode 124 having different thicknesses in the first region P1 and the second region P2 are formed.

Referring to FIG. 30, a gate insulating layer 140 covering the gate line 121 and the gate electrode 124 is formed on the substrate 110 such that the step having the first upper surface US1 and the second upper surface US2 having different heights may be formed. The step in the second region P2 is lower than the step in the first region P1.

A first silicon layer 150, a second silicon layer 160, and a data conductive material 170 are sequentially deposited on the gate insulating layer 140. The first silicon layer 150 may be made of amorphous silicon, polysilicon, or an oxide semiconductor, and the second silicon layer 160 may be made of amorphous silicon doped with an impurity or of a silicide.

Referring to FIG. 31 and FIG. 32, the data conductive material 170 is patterned to form a data conductive layer pattern 172, and the second silicon layer 160 and the first silicon layer 150 are sequentially etched using the data conductive layer pattern 172 as a mask to form an ohmic contact layer pattern 161 and a semiconductor layer 151. In contrast to conventional methods, the data conductive layer pattern 172 is not separated into the source electrode and the drain electrode by photolithography, which as explained above may cause misalignment of the source and drain electrodes with the gate electrode.

Referring to FIG. 33, a planarization layer PO covering the data conductive layer pattern 172 is formed on the gate insulating layer 140. The planarization layer PO completely covers the data conductive layer pattern 172 that is raised by the thickness of the gate line 121 and the gate electrode 124. The planarization layer PO may be made of an insulating material such as an organic material, silicon nitride, or silicon oxide.

Referring to FIG. 34, the planarization layer PO is dry-etched to expose the protruding portion of the data conductive layer pattern 172 that is raised by the thickness of the gate electrode 124. Only the data conductive layer pattern 172 of the first region P1 is exposed, and the data conductive layer pattern 172 of the second region P2 is not exposed. The exposed data conductive layer pattern 172 is self-aligned with the gate electrode 124.

Referring to FIG. 35, the exposed data conductive layer pattern 172 is wet-etched to expose the ohmic contact layer pattern 161 of the first region P1.

Referring to FIG. 36, the exposed ohmic contact layer pattern 161 is dry-etched. Here, the exposed semiconductor 154, the semiconductor stripe 151 extending in the longitudinal direction, and the ohmic contact layers 161 and 163 may be formed at the portions positioned on the first upper surface US1 of the gate insulating layer 140. The source electrode 173 and the drain electrode 175 that are separated from each other with respect to the exposed semiconductor 154 may be formed. The semiconductor 154 may be formed by etching a portion of the upper surface of the ohmic contact layer pattern 161. The data line 171 may be formed in the second region P2. A passivation layer 180 covering the exposed semiconductor 154 positioned on the first upper surface US1 is formed on the planarization layer PO to manufacture the thin film transistor array panel shown in FIG. 24.

While this invention has been described in connection with exemplary embodiments, it will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

What is claimed is:

1. A method for manufacturing a thin film transistor array panel, the method comprising:
forming a gate line comprising a gate electrode on a substrate;
forming a gate insulating layer on the gate line and the gate electrode;
forming a semiconductor layer on the gate insulating layer;
forming a data line comprising a data conductive layer pattern on the semiconductor layer, the data line crossing the gate line;
forming a planarization layer on the data conductive layer pattern;
first etching the planarization layer to expose a portion of the data conductive layer pattern overlapping the gate electrode;
second etching the exposed data conductive layer pattern; and
exposing a portion of the semiconductor layer overlapping the gate electrode.

2. The method of claim 1, wherein the semiconductor layer comprises a semiconductor formed on the gate insulating layer and an ohmic contact layer formed on the semiconductor,
the second etching of the exposed data conductive layer pattern comprises exposing an upper surface of the ohmic contact layer by wet-etching the exposed data conductive layer, and
the upper surface of the exposed ohmic contact layer is dry-etched to expose a portion of the semiconductor overlapping the gate electrode.

3. The method of claim 2, wherein the data conductive layer pattern on the ohmic contact layer is divided into a source electrode and a drain electrode after the wet-etching of the exposed data conductive layer pattern.

4. The method of claim 3, further comprising forming a passivation layer on the exposed semiconductor layer and the planarization layer,
wherein the passivation layer contacts the semiconductor layer on a first upper surface of the gate insulating layer, and the passivation layer contacts the planarization layer on a second upper surface of the gate insulating layer.

5. The method of claim 4, wherein forming the data conductive layer pattern comprises:
depositing a data conductive material on the semiconductor layer;
patterning the data conductive material; and
patterning the semiconductor layer by using the patterned data conductive material as a mask.

6. The method of claim 1, wherein forming the gate line comprises:
depositing a gate conductive material on the substrate; and
patterning the gate conductive material to form a first gate line portion and a second gate line portion having different thicknesses from each other,
wherein the first gate line portion corresponds to the gate electrode, the second gate line portion corresponds to the portion where the gate line and the data line cross each other, and a thickness of the first gate line portion is greater than a thickness of the second gate line portion.

7. The method of claim 6, wherein forming the first gate line portion and the second gate line portion comprises:
forming a first photosensitive film corresponding to the first gate line portion and a second photosensitive film corresponding to the second gate line portion;
etching the gate conductive material using the first photosensitive film and the second photosensitive film as a mask;
etching the second photosensitive film through an etch back process; and
etching the second gate line portion to have a thickness less than a thickness of the first gate line portion.

8. The method of claim 7, wherein the planarization layer exposes the data line disposed on the first gate line portion and covers the data line disposed on the second gate line portion.

9. A thin film transistor array panel, comprising:
a substrate;
a gate line disposed on the substrate and comprising a gate electrode;
a gate insulating layer disposed on the gate electrode and comprising a first upper surface and a second upper surface of different heights;
a semiconductor layer disposed on the gate insulating layer;
a data line comprising a data conductive layer disposed on the second upper surface of the gate insulating layer and crossing the gate line; and
a planarization layer disposed on the data conductive layer and comprising an opening corresponding to the first upper surface of the gate insulating layer,
wherein the height of the first upper surface is greater than the height of the second upper surface.

10. The thin film transistor array panel of claim 9, further comprising a passivation layer disposed on the semiconductor layer and the planarization layer,
wherein the passivation layer contacts the semiconductor layer on the first upper surface of the gate insulating layer, and the passivation layer contacts the planarization layer on the second upper surface of the gate insulating layer.

11. The thin film transistor array panel of claim 10, wherein the semiconductor layer comprises:
a semiconductor disposed on the gate insulating layer; and
an ohmic contact layer disposed on the semiconductor.

12. The thin film transistor array panel of claim 11, wherein a width of the opening of the planarization layer and a width of the gate electrode are self-aligned to each other.

13. The thin film transistor array panel of claim 9, wherein the planar shape of the semiconductor layer is substantially the same as the planar shape of the data conductive layer outside of the opening.

14. The thin film transistor array panel of claim 9, wherein the semiconductor layer comprises an oxide semiconductor.

15. The thin film transistor array panel of claim 9, wherein the gate line comprises a first gate line portion corresponding to the gate electrode and a second gate line portion corresponding to the crossing of the gate line and the data line, and
a thickness of the first gate line portion is greater than a thickness of the second gate line portion.

16. The thin film transistor array panel of claim 15, wherein the data line disposed on the second gate line portion is covered by the planarization layer.

17. A method for manufacturing a thin film transistor, the method comprising:
forming a gate electrode on a substrate;
forming a gate insulating layer on the gate electrode;
forming a data conductive layer pattern on the gate insulating layer;
forming a planarization layer on the data conductive layer pattern;
first etching the planarization layer to expose a portion of the data conductive layer pattern overlapping the gate electrode;
second etching the exposed data conductive layer pattern to expose a portion of the gate insulating layer overlapping the gate electrode;
removing the planarization layer; and
forming a semiconductor pattern covering the exposed gate insulating layer on the data conductive layer pattern.

18. The method of claim 17, wherein the first etching comprises dry-etching, the second etching comprises wet-etching, and the data conductive layer pattern is divided into a source electrode and a drain electrode after the wet-etching of the exposed data conductive layer pattern.

19. The method of claim 18, further comprising forming an ohmic contact layer on the gate insulating layer before forming the planarization layer.

20. The method of claim 19, wherein the ohmic contact layer and the data conductive layer pattern are formed using the same mask.

21. A thin film transistor, comprising:
a substrate;
a gate electrode disposed on the substrate;
a gate insulating layer disposed on the gate electrode and comprising:
a first upper surface and a second upper surface having different heights from each other and;
a lateral surface connecting the first upper surface and the second upper surface;
a data conductive layer disposed on the second upper surface and the lateral surface of the gate insulating layer; and
a semiconductor layer disposed on the first upper surface and the lateral surface of the gate insulating layer,
wherein the data conductive layer is interposed between the gate insulating layer and the semiconductor layer on the lateral surface of the gate insulating layer.

22. The thin film transistor of claim 21, further comprising an ohmic contact layer disposed between the data conductive layer and the semiconductor layer on the lateral surface of the gate insulating layer.

23. The thin film transistor of claim 22, wherein the semiconductor layer comprises an oxide semiconductor.

24. A thin film transistor array panel, comprising:
a substrate;
a gate electrode disposed on the substrate;
a gate insulating layer disposed on the gate electrode and comprising a first upper surface and a second upper surface having different heights from each other;
a semiconductor layer, corresponding to the gate electrode, disposed on the gate insulating layer;
a source electrode disposed on the second upper surface;
a drain electrode disposed on the second upper surface and facing the source electrode, the drain electrode and the source electrode being separated by at least a width of the first upper surface of the gate insulating layer; and
a planarization layer disposed on the drain electrode and the source electrode and comprising an opening corresponding to the first upper surface of the gate insulating layer,
wherein the height of the first upper surface is greater than the height of the second upper surface, and
the source electrode and the drain electrode are self-aligned to the gate electrode.

25. The thin film transistor array panel of claim 24, further comprising an ohmic contact layer disposed between the semiconductor layer and the source electrode and the drain electrode.

26. The thin film transistor array panel of claim 24, wherein a portion of the semiconductor layer, corresponding to the second upper surface of the gate insulating layer, is disposed between gate insulating layer and the source electrode and the drain electrode.

27. The thin film transistor array panel of claim 26, further comprising a passivation layer disposed on the planarization layer.

28. The thin film transistor array panel of claim 24, wherein the semiconductor layer is disposed on the first upper surface of the gate insulating layer but is not disposed on the second upper surface of the gate insulating layer.

29. The thin film transistor array panel of claim 28, further comprising a passivation layer disposed on the planarization layer.

30. The thin film transistor array panel of claim 24, wherein the semiconductor layer comprises an oxide semiconductor.
